(19) United States
(12) Patent Application Publication
(10) Pub. No.: US 2015/0047697 A1
(43) Pub. Date: Feb. 19, 2015

(54) TRANSPARENT CONDUCTIVE COATINGS FOR USE IN HIGHLY FLEXIBLE ORGANIC PHOTOVOLTAIC FILMS ON THIN FLEXIBLE SUBSTRATES WITH PRESSURE-SENSITIVE ADHESIVES

(71) Applicants: John Anthony CONKLIN, Apalachin, NY (US); Scott Ryan HAMMOND, Wheat Ridge, CO (US)

(72) Inventors: John Anthony CONKLIN, Apalachin, NY (US); Scott Ryan HAMMOND, Wheat Ridge, CO (US)

(73) Assignee: NEW ENERGY TECHNOLOGIES, INC., Columbia, MD (US)

(21) Appl. No.: 14/317,982

(22) Filed: Jun. 27, 2014

Related U.S. Application Data
(60) Provisional application No. 61/841,243, filed on Jun. 28, 2013.
(60) Provisional application No. 61/842,355, filed on Jul. 2, 2013.
(60) Provisional application No. 61/841,244, filed on Jun. 28, 2013.
(60) Provisional application No. 61/842,357, filed on Jul. 2, 2013.
(60) Provisional application No. 61/841,247, filed on Jun. 28, 2013.
(60) Provisional application No. 61/842,365, filed on Jul. 2, 2013.
(60) Provisional application No. 61/841,248, filed on Jun. 28, 2013.
(60) Provisional application No. 61/842,372, filed on Jul. 2, 2013.
(60) Provisional application No. 61/842,796, filed on Jul. 3, 2013.
(60) Provisional application No. 61/841,251, filed on Jun. 28, 2013.
(60) Provisional application No. 61/842,375, filed on Jul. 2, 2013.
(60) Provisional application No. 61/842,803, filed on Jul. 3, 2013.

(51) Int. Cl. H01L 51/44; H01L 51/42; B32B 37/24

(52) U.S. Cl. CPC H01L 51/445; B32B 37/24; H01L 51/4253; B32B 2037/243; B32B 2367/00; B32B 2307/202; B32B 2386/00; B32B 2323/04; B32B 2311/08; B32B 2313/04
USPC 136/256; 156/280

(57) ABSTRACT

Flexible transparent conductive films, flexible OPV devices, and semitransparent flexible OPV devices, and methods for the fabrication of flexible transparent conductive films, and the use of those films in fabricating flexible OPV devices, and semitransparent flexible OPV devices are presented. High-throughput and low-cost fabrication options also allow for economical production.

### CROSS-REFERENCE TO RELATED APPLICATIONS

This application claims priority under 35 U.S.C. 119(e) of U.S. Provisional Application No. 61/841,243, filed on Jun. 28, 2013 (Attorney Docket No. 7006/0141PR01), U.S. Provisional Application No. 61/842,355, filed on Jul. 2, 2013 (Attorney Docket No. 7006/0141PR02), U.S. Provisional Application No. 61/841,244, filed on Jun. 28, 2013 (Attorney Docket No. 7006/0142PR01), U.S. Provisional Application No. 61/842,357, filed on Jul. 2, 2013 (Attorney Docket No. 7006/0142PR02), U.S. Provisional Application No. 61/841,247, filed on Jun. 28, 2013 (Attorney Docket No. 7006/0143PR01), U.S. Provisional Application No. 61/842,365, filed on Jul. 2, 2013 (Attorney Docket No. 7006/0143PR02), U.S. Provisional Application No. 61/841,248, filed on Jun. 28, 2013 (Attorney Docket No. 7006/0144PR01), U.S. Provisional Application No. 61/842,372, filed on Jul. 02, 2013 (Attorney Docket No. 7006/0144PR02), U.S. Provisional Application No. 61/842,796, filed on Jul. 3, 2013 (Attorney Docket No. 7006/0145PR01), U.S. Provisional Application No. 61/841,251, filed on Jun. 28, 2013 (Attorney Docket No. 7006/0146PR01), U.S. Provisional Application No. 61/842,375, filed on Jul. 2, 2013 (Attorney Docket No. 7006/0146PR02) and U.S. Provisional Application No. 61/842,803, filed on Jul. 3, 2013 (Attorney Docket No. 7006/0147PR01); the entire contents of all the above identified patent applications are hereby incorporated by reference in their entirety. This application is related to Applicants' co-pending U.S. applications, which are filed concurrently herewith on Jun. 27, 2014, 7006/0141PUS01, 7006/0142PUS01, 7006/0143PUS01, 7006/0144PUS01, 7006/0145PUS01 and 7006/0146PUS01; each of which is incorporated herein by reference in its entirety.

### FIELD OF THE INVENTION

The present invention is directed to a method for the preparation and use of transparent conductive coatings in highly flexible OPV devices, comprised of one of more cells connected in series and/or parallel, including semitransparent OPV devices prepared on very thin flexible substrates with pressure sensitive adhesives.

### BACKGROUND OF THE INVENTION

OPV is an inherently flexible technology, which presents attractive potential applications that are incompatible with conventional inorganic photovoltaic materials. For example, Kaltenbrunner et. at (Nature Comm. DOI: 10.1038/ncomms1772) has demonstrated that by using very thin substrates, supported with temporary substrates and coated via conventional spin coating techniques, very flexible OPV devices can be prepared with comparable performance to those produced on rigid substrates, and the devices can survive extreme elastic deformations.

### SUMMARY OF THE INVENTION

The present application recognizes that the properties described by Kaltenbrunner et. at (Nature Comm. DOI: 10.1038/ncomms1772) can be adapted and taken advantage of to provide novel methods for the preparation and use of highly flexible OPV devices.

Despite the work of Kaltenbrunner et. at (Nature Comm. DOI: 10.1038/ncomms1772), the vast majority of OPV devices are not flexible, however, due to metallic conductor, typically a layer of indium tin oxide (ITO), and a highly crystalline transparent conductive oxide (TCO). All OPV devices require at least one transparent conductor (TC), which allows light to enter the device and reach the photoactive layer, while still transporting charge vertically and laterally to allow charge extraction from the device. ITO remains the TC of choice for most applications due to its favorable sheet resistance (Rₛ)/transparency tradeoff properties; it can have low Rₛ values of ˜20 Ω/sqr for reasonable visible light transmission (VLT) values of ˜80%. ITO is extremely brittle, however, due to its highly crystalline nature, which leads to cracking at low tensile stresses, resulting in large increases in the Rₛ. As a result, ITO, along with many related crystalline TCOs are incompatible with flexible OPV devices.

The work of Kaltenbrunner et. at (Nature Comm. DOI: 10.1038/ncomms1772) utilized high conductivity poly(ethylenedioxythiophene):poly(styrene sulfonate) [PEDOT:PSS] as the flexible TC material for their OPV devices. High conductivity PEDOT:PSS is well known for its TC properties, its flexibility, and for its charge-collection layer properties. Low-conductivity PEDOT:PSS is often used as a hole-collection layer in standard and inverted architecture OPV devices, which is used to create hole-selectivity at an electrode; and high conductivity PEDOT:PSS can play both roles simultaneously. High conductivity PEDOT:PSS has several limitations as a TC material, however, importantly a relatively high Rₛ of around 80 Ω/sqr for 80% VLT. This relatively high Rₛ value, as compared to ITO, contributes to significant series resistance in large-area devices, where charges must travel significant lateral distances, whereas the work of Kaltenbrunner et. at (Nature Comm. DOI: 10.1038/ncomms1772) involved small devices of ˜0.1 cm². Additionally, that work utilized the low work-function metal calcium as the effective electron-collection layer, topped by a silver metal electrode. While these ductile metals are inherently flexible, calcium is very reactive, spontaneously reacting with water and/or oxygen to produce insulating calcium oxide. As such, these devices have very poor lifetimes, and would be impractical for commercial products.

For semitransparent OPV devices, which are desirable for a number of applications, including SolarWindow™ (the subject of several US patent applications by Applicants), both electrodes must include TC materials. Due to the energy level alignment of PEDOT:PSS, which provides its hole-selectivity, it cannot serve as both TC materials, regardless of the Rₛ limitations discussed previously. Thus, other inherently flexible TC contacts are required for flexible semitransparent organic devices, and to maximize the performance of large-area devices, TCs with lower Rₛ values are desirable as well.

The present invention recognizes that conventional transparent conductor materials suffer from brittleness, high sheet resistance, charge selectivity, and/or other factors that restrict their use in flexible OPV devices, particularly semitransparent flexible OPV devices.

These problems and others are addressed by the present invention, a first exemplary embodiment of which comprises a method for the preparation of a flexible TC material supported by a very thin, highly flexible substrate, which can then be used to prepare flexible OPV devices. The highly flexible substrate, such as a very thin polyethylene terephthalate (PET) foil, is supported by a more rigid support substrate to facilitate device fabrication, with a transfer release layer incorporated to allow facile removal of the support substrate (and the release layer) after fabrication of the device. The thin substrate is then coated with an inherently flexible TC material. There are a number of such TC materials that may be used in this invention, including but not limited to: conductive polymers, such as high conductivity PEDOT:PSS; metal nanowire or carbon nanotube meshes; continuous graphene sheets or small overlapping graphene sheets; amorphous TCOs such as aluminum-doped zinc oxide (AZO), gallium-doped zinc oxide (GZO), or indium-doped zinc oxide (IZO); or any combinations thereof

In one exemplary embodiment of the invention, the TC material comprises high conductivity PEDOT:PSS blended with silver nanowires, which increases the conductivity and reduces the Rₛ values compared to that of PEDOT:PSS alone, while maintaining or improving VLT, and simultaneously providing mechanical stability to the silver nanowires. Such a system has the benefit of being solution processable, enabling low-cost, high-throughput roll-to-roll, sheet-to-sheet, graveur, etc. coating methods for manufacturing.

In another exemplary embodiment, the TC material comprises one of the amorphous TCOs such as AZO, GZO, IZO, etc. These materials have the benefit of having very low Rₛ values and reasonable VLTs, both comparable to those of ITO, while still being flexible due to their amorphous nature. These materials generally require sputter-deposition, and/or very high processing temperatures, however, which can complicate their use, increase costs, and decrease throughput.

In another exemplary embodiment, the TC material comprises graphene dispersions blended with silver nanowires. While the consensus in the literature appears to be that graphene by itself, either in continuous sheets or small overlapping sheets, does not have sufficient conductivity to be an attractive TC material, in combination with silver nanowires, it may prove to have attractive TC properties due to the favorable combination of one-dimensional and two-dimensional conductors. Additionally, such a combination is both inherently flexible and potentially compatible with solution processing, particularly when utilizing dispersions of small graphene flakes.

The afore-mentioned flexible TC materials are provided for descriptive purposes only, and are not meant to be exhaustive in nature.

A further exemplary embodiment of the invention comprises a method for the preparation of a flexible OPV device, comprising one or more cells connected in series and/or parallel, on the flexible TC material described in the previous exemplary embodiments. After the TC material is deposited on the thin flexible substrate, which is laminated on the supporting substrate and release layer, the rest of the flexible multilayer OPV device may be deposited. This may include a charge-collection layer (CCL), followed by the photoactive layer, which generally comprises a bulk heterojunction (BHJ) between an electron-donor and an electron acceptor material. This may be followed by an additional CCL, of opposite polarity as the first one. The materials and methods for deposition of these layers is known to those skilled in the art of OPV, and generally can be compatible with solution-processing to ensure low-costs and high-throughput. Next, a ductile top metal electrode is deposited, such as silver. Metal electrodes can be deposited via a number of methods, from screen-printing to evaporation, some of which are compatible with high-throughput, roll-to-roll, sheet-to-sheet, graveur, etc. coating methods for manufacturing methods. In some embodiments, when the device being fabricated is a module, there may be additional processing steps, such as laser and/or mechanical scribing, to allow fabrication of series and/or parallel interconnected devices. In some embodiments, these steps may be located in between device layer deposition steps, and in some embodiments, these may be performed at the end. After the flexible OPV device is completed, a pressure-sensitive adhesive is applied to the surface of the device using coating techniques as known to those skilled in the art. The thin, flexible substrate along with the completed OPV device, including TC, may then be removed from the supporting substrate using the release layer to provide a very thin, highly flexible OPV device that may be adhered to objects of arbitrary shape.

An additional exemplary embodiment of the invention comprises a method for the preparation of a semitransparent flexible OPV device, comprising one or more cells connected in series and/or parallel, on the flexible TC material described in the previous exemplary embodiments. As in the previous embodiments, the initial flexible TC layer is then coated with the remainder of the layers of a semitransparent OPV device, as is known to those skilled in the art of OPV. Such layers may include one or two CCL layers, sandwiching the BHJ layer. In either case, the BHJ is chosen such that the light absorption of the materials ensures a reasonable degree of VLT and attractive aesthetics. In all cases, the final layer of the semitransparent OPV device comprises another TC layer, rather than a metal layer. If the TC layer does not also function as a CCL, then the same TC can be used on both sides of the device. If the TC layer does function as a CCL, such as PEDOT:PSS (alone or in blends), then it cannot be used on both sides of the device, and an alternative flexible TC material must be chosen, such as one of those from the previous exemplary embodiments. The TC layers must be chosen appropriately, along with the CCL layers, to ensure proper energy level alignment to ensure favorable electron and hole transport in the devices, as known to those skilled in the art. After the TC layer is deposited, a metal grid may be deposited as well, to aid in current collection/transport. As previously described, in some example embodiments, additional processing steps may be performed to enable fabrication of series- and/or parallel-interconnected modules. After the semitransparent OPV device is completed, a pressure-sensitive adhesive is applied to the surface of the device using coating techniques as known to those skilled in the art. The thin, flexible substrate along with the completed semitransparent OPV device may then be removed from the support substrate and release layer, and adhered to semitransparent objects of arbitrary shapes, such as curved windows or plastic canopy's and fixtures.

Other features and advantages of the present invention will become apparent to those skilled in the art upon review of the following detailed description and drawings.

### BRIEF DESCRIPTION OF THE DRAWINGS

These and other aspects and features of embodiments of the present invention will be better understood after a reading of the following detailed description, together with the attached drawings, wherein:

FIG. 1 is a cross-sectional view of a flexible transparent conductor, coated on a thin flexible substrate with a transfer release layer and support layer, which can be used to prepare flexible OPV devices, according to an exemplary embodiment of the invention.

FIG. 2 is a cross-sectional view of a flexible OPV device coated onto the flexible transparent conductor film of FIG. 1, including charge-collection layers, the bulk heterojunction layer, a ductile top metal electrode, and a pressure-sensitive adhesive layer, according to an exemplary embodiment of the invention.

FIG. 3 is a cross-sectional view of a flexible semitransparent OPV device coated onto the flexible transparent conductor film of FIG. 1, including charge-collection layers, the bulk heterojunction layer, a second transparent conductor, and a pressure-sensitive adhesive layer, according to an exemplary embodiment of the invention.

### DETAILED DESCRIPTION OF THE EXEMPLARY EMBODIMENTS OF THE INVENTION

The present invention now is described more fully hereinafter with reference to the accompanying drawings, in which embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

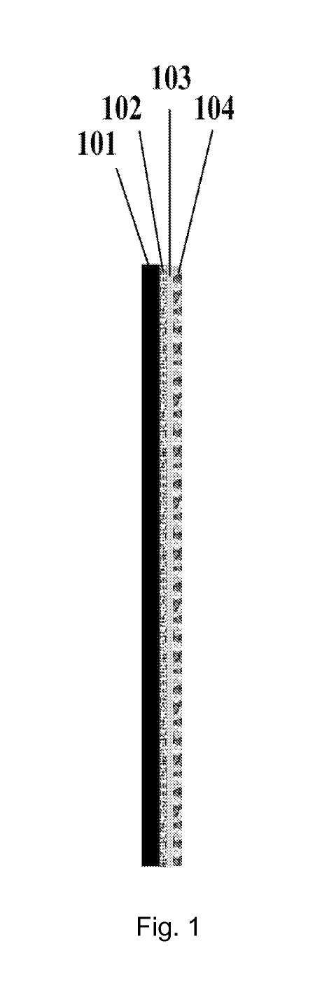

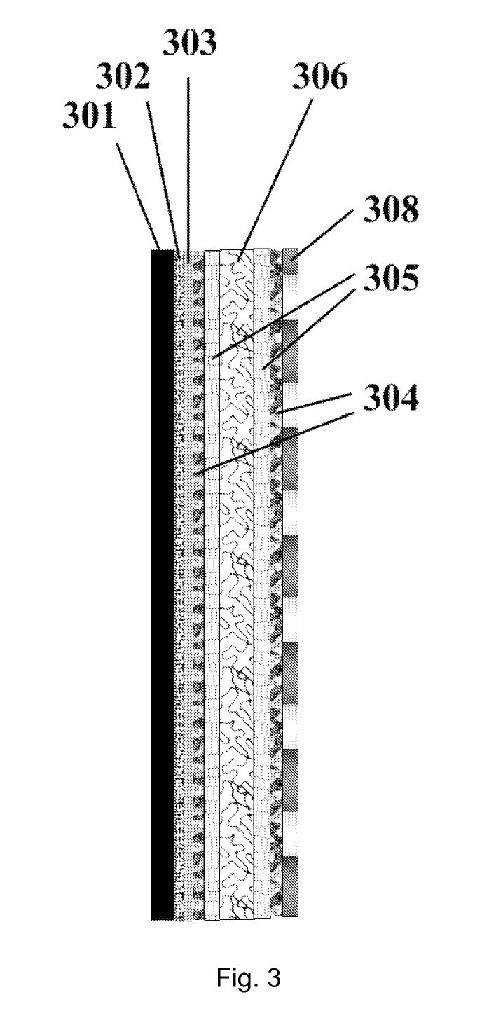

Referring now to the drawings, FIGS. 1-3 illustrate exemplary embodiments of the method for preparing and using flexible transparent conductors in the production of flexible OPV devices (FIGS. 1-3), including semitransparent OPV devices (FIG. 3).

Referring to FIG. 1, which provides a cross-sectional view of a flexible TC film for the preparation of flexible OPV devices, the film is prepared upon a temporary support layer 101, in order to provide sufficient rigidity to allow conventional manufacturing techniques, including high-speed roll-to-roll, sheet-to-sheet, graveur, etc. coating methods. The support layer can include glass or thick metal rigid substrates, flexible polymer or metal foils, or any convenient substrate material, depending on the chosen manufacturing methods. On top of the support layer is a transfer release layer 102 that allows easy removal of the support layer and transfer layer from the thin flexible substrate 103, which are all laminated together as known to those skilled in the art. The thin flexible substrate is any appropriate substrate material that is highly flexible and transparent, such as very thin polymer foils, including but not limited to polyethyleneterephthalate (PET). On top of this is coated a TC material 104, which can include a number of materials, including but not limited to: conductive polymers, such as high conductivity PEDOT:PSS; metal nanowire or carbon nanotube meshes; continuous graphene sheets or small overlapping graphene sheets; amorphous TCOs such as aluminum-doped zinc oxide (AZO), gallium-doped zinc oxide (GZO), or indium-doped zinc oxide (IZO); or any combinations thereof. The coating methodology depends on the specific materials chosen, and is known to those skilled in the art.

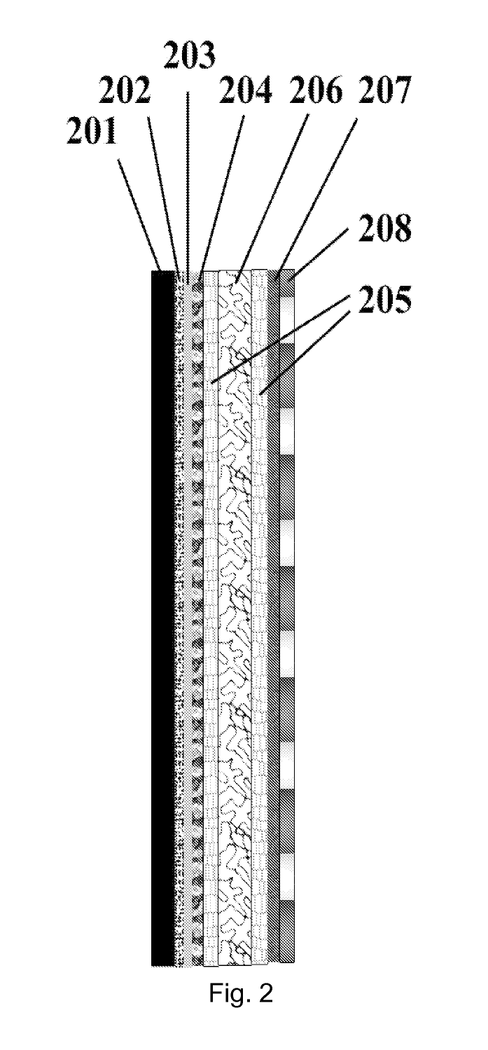

Referring to FIG. 2, which provides a cross-sectional view of a flexible OPV device prepared from the flexible TC film of FIG. 1, the film is prepared upon a temporary support layer 201. On top of the support layer is a transfer release layer 202 that allows easy removal of the support layer and transfer layer from the thin flexible substrate 203, which are all laminated together. On top of the flexible substrate is the TC material 204. Coated on top of the TC is the rest of the flexible OPV device, including two CCLs 205, sandwiching the BHJ 206, the ductile metal top contact 207, and the pressure-sensitive adhesive 208, that allows the flexible OPV device to be adhered to objects of arbitrary shape. In this exemplary embodiment, the CCLs are necessarily different materials with opposing polarities, and the CCLs, TC, BHJ and metal electrode materials all must be chosen to have appropriate energy levels to ensure favorable electron transport in the device, as known to those skilled in the art.

Referring to FIG. 3, which provides a cross-sectional view of a semitransparent flexible OPV device prepared from the flexible TC film of FIG. 1, the film is prepared upon a temporary support layer 301. On top of the support layer is a transfer release layer 302 that allows easy removal of the support layer and transfer layer from the thin flexible substrate 303, which are all laminated together. On top of the flexible substrate is the TC material 304. Coated on top of the TC is the rest of the flexible OPV device, including two CCLs 305, sandwiching the BHJ 306, a second TC material 304, and the pressure-sensitive adhesive 308, that allows the semitransparent flexible OPV device to be adhered to semitransparent objects of arbitrary shape. Again, in this exemplary embodiment, the CCLs are necessarily different materials with opposing polarities, while the TCs may or may not be identical materials, depending on the nature of the TC materials chosen. In the exemplary embodiment, the CCLs, TCs, and BHJ materials all must be chosen to have appropriate energy levels to ensure favorable electron transport in the device, as known to those skilled in the art.

The present invention has been described herein in terms of several preferred embodiments. However, modifications and additions to these embodiments will become apparent to those of ordinary skill in the art upon a reading of the foregoing description. It is intended that all such modifications and additions comprise a part of the present invention to the extent that they fall within the scope of the several claims appended hereto.

What is claimed is:

1. A flexible transparent contact film for the production of flexible OPV devices comprising:
a support substrate,
a transfer release layer laminated between the support substrate and
a very thin, highly flexible transparent substrate, such as PET, and
a transparent contact layer

2. The flexible film of claim 1, wherein the support substrate is a rigid material such as glass or thick metal.

3. The flexible film of claim 1, wherein the support substrate is a flexible material, such as a polymer or metal foil compatible with roll-to-roll manufacturing techniques.

4. The flexible film of claim 1, wherein the transparent contact material comprises a blend of PEDOT:PSS and silver nanowires.

5. The flexible film of claim 1, wherein the transparent contact material comprises a blend of small graphene flakes and silver nanowires.

6. The flexible film of claim 1, wherein the transparent contact material comprises an amorphous transparent conductive oxide such as aluminum-, gallium-, and/or indium-doped zinc oxide.

7. A method for the manufacture of the flexible transparent conductor film of claim 3, wherein:
the flexible foil is coated with the transfer release material,
laminated with the very thin, highly flexible transparent substrate, such as PET, and coated with the transparent contact material,
all in a roll-to-roll, sheet-to-sheet, graveur, etc. coating methods for manufacturing manner,
and utilizing solution-processing,
to allow low-cost, high-throughput manufacturing.

8. A method for the manufacture of the flexible transparent conductor film of claim 4, wherein:
the flexible foil is coated with the transfer release material,
laminated with the very thin, highly flexible transparent substrate, such as PET, and coated with the amorphous transparent conducting oxide materials,
utilizing roll-to-roll or sheet-to-sheet compatible sputtering systems, to minimize cost and maximize throughput.

9. A flexible OPV device film produced utilizing the flexible transparent contact film of claim 1, comprising:
a charge-collection layer coated on top of the transparent conducting film,
a bulk heterojunction photoactive layer coated on top of the first charge-collection layer,
a second charge-collection layer, of opposite polarity as the first charge-collection layer, coated on top of the bulk heterojunction,
a ductile top metal electrode deposited on top of the second charge-collection layer,
and a pressure-sensitive adhesive coated on top of the metal electrode to enable adhesion of the flexible OPV device to objects of arbitrary shape.

10. The flexible OPV device film of claim 9, wherein the first transparent conductor also functions as the first charge-collection layer in the OPV device.

11. A semitransparent flexible OPV device film produced utilizing the flexible transparent contact film of claim 1, comprising:
a charge-collection layer coated on top of the transparent conducting film,
a bulk heterojunction photoactive layer coated on top of the first charge-collection layer,
a second charge-collection layer, of opposite polarity as the first charge-collection layer, coated on top of the bulk heterojunction,
a second transparent conducting layer coated on top of the second charge-collection layer,
and a pressure-sensitive adhesive coated on top of the second transparent conductor to enable adhesion of the semitransparent flexible OPV device to semitransparent objects of arbitrary shape.

12. The flexible semitransparent OPV device film of claim 11, wherein the first transparent conductor and second transparent conductor are made of identical materials comprised of an amorphous transparent conductive oxide such as aluminum-, gallium-, and/or indium-doped zinc oxide.

13. The flexible semitransparent OPV device film of claim 11, wherein the first transparent conductor and second transparent conductor are made of different materials, one of which comprises a blend of PEDOT:PSS and silver nanowires.
